(19) United States
(12) Patent Application Publication
(10) Pub. No.: US 2026/0269707 A1
(43) Pub. Date: Sep. 10, 2026

(54) BEAT FREQUENCY MODULATED SINGLE-STAGE SOFT-SWITCHED MICROINVERTER

(71) Applicant: The Governors of the University of Alberta, Edmonton (CA)

(72) Inventors: Sayed Ali Khajehoddin, Edmonton (CA); Milad Heidari Khouzani, Edmonton (CA); Mohammad Ebrahimi

(73) Assignee: The Governors of the University of Alberta, Edmonton, AB (CA)

(21) Appl. No.: 19/165,635

(22) PCT Filed: Mar. 18, 2024
(86) PCT No.: PCT/CA2024/050323

§ 371 Date: Sep. 16, 2025

Related U.S. Application Data
(60) Provisional application No. 63/452,725, filed on Mar. 17, 2023.

(51) Int. Cl. H02M 1/00; H02M 5/458; H02S 40/32

(52) U.S. Cl. CPC H02M 1/0058; H02M 5/4585; H02S 40/32

(57) ABSTRACT

A Beat Frequency Modulation (BFM) system for generating a low frequency reference waveform including two or more converters, a frequency control module, and a rectifier. The converters are connected in series, parallel, or cascaded. Each converter includes a power switch configured to generate a high frequency power signal controlled by BFM modules at their respective outputs. The frequency control module is configured to operate a BFM carrier signal of each of the converters at different frequencies, thereby creating an envelope of a resulting signal containing a desired low frequency reference signal. The rectifier is connected to outputs of the converters and configured to rectify the high frequency signal with the low frequency envelope shape, thereby generating a low frequency sinusoidal waveform.

### RELATED APPLICATIONS

This application claims priority benefit of U.S. Provisional Application Ser. No. 63/452,725 filed 17 Mar. 2023; the contents of which are hereby incorporated by reference.

### FIELD OF THE INVENTION

The present invention generally relates to microinverters for photovoltaic (PV) systems, and more specifically to single-stage single-phase microinverters with soft-switching with fully soft-switching operation for a wide range of input voltage and output load based on beat frequency modulation (BFM).

### BACKGROUND

Nowadays, photovoltaic (PV) systems are widely utilized in renewable energy systems due to their low costs and large power generation capacity [1]. To convert the low-level DC voltage of the PV panel (20~40V) to the desired AC voltage of the grid, a switching DC-AC power converter is required which is called the microinverter. In general, microinverters can be categorized into four groups according to the galvanic isolation (isolated and non-isolated structures), and the number of stages (single-stage and two-stage structures) [2].

To improve the power density of the power converter and decrease the cost and volume, the switching frequency of the converter should increase. However, higher frequency operation results in higher switching losses that reduce the converter efficiency. Therefore, soft-switching techniques are required to eliminate switching losses of the converter. Several topologies and control schemes have been presented in recent years for various applications to improve the efficiency and reliability of microinverters [3]-[9]. A non-isolated single-phase ZVS inverter is introduced in [4], in which an auxiliary resonant circuit is utilized to provide soft-switching conditions. However, isolated structures are more suitable for PV applications when amplification and galvanic isolation is needed. Therefore, some researchers have introduced Flyback-based microinverters to provide both isolation and amplification, as well as single-stage operation [5]-[6]. However, these types of microinverters utilize auxiliary circuits to provide soft-switching for the converter switches, which complicate the control system and restrain the converter's performance for higher frequencies. Some others have proposed dual active bridge (DAB) based microinverters with no auxiliary circuits, to provide soft-switching operation and high efficiency in high-power applications [7]-[8]. Even though the auxiliary circuits are not employed in [8], a high number of components are utilized due to its two-stage configuration, which leads to more cost and volume, and more complex control designs. Thus, single-stage topologies are preferred in PV applications due to their lower power losses and lower number of components. A single-stage DAB-based microinverter is presented in [9], in which a sinusoidal modulation is combined with the phase shift modulation of the DAB structure to provide soft-switching conditions. However, the control scheme of the presented microinverter is still complex to provide soft-switching operation for a wide range of input voltage and output load

Accordingly, there exists a need for a single-stage single-phase microinverter with a fully soft-switching operation for a wide range of input voltage and output load. There further exists a need for such a microinverter that utilizes a low number of components with a simple control strategy, which results in a low-cost and low-volume microinverter for high-frequency and highly efficient applications.

### SUMMARY OF THE INVENTION

The present invention provides a Beat Frequency Modulation (BFM) system for generating a low frequency reference waveform. The BFM system includes two or more converters, a frequency control module, and a rectifier. The two or more converters are connected in series or parallel or cascaded. Each converter includes at least a power switch configured to generate a high frequency power signal controlled by BFM modules at their respective outputs. The frequency control module is configured to operate a BFM carrier signal of each of the converters at different frequencies, thereby creating an envelope of a resulting signal containing a desired low frequency reference signal. The rectifier is connected to outputs of the converters, the rectifier configured to rectify the high frequency signal with the low frequency envelope shape, thereby generating a low frequency sinusoidal waveform.

The present invention additionally provides a microinverter for use with a photovoltaic (PV) system. The microinverter includes an LC resonant tank and a magnetizing inductance Lₘ electrically connected to the LC resonant tank, wherein the LC resonant tank and the magnetizing inductance Lₘ form an LLC resonant network. The LC resonant tank includes a first resonant LC converter configured to generate a first current having a frequency of a sinusoidal current of F₀; a second resonant LC converter configured to generate a second current having a frequency of a sinusoidal current of F₀+2F_{g}, where f₀ is the switching frequency of the first resonant LC converter and f_{g} is a grid frequency; and a first switching leg associated with the first resonant LC converter and a second switching leg associated with the second resonant LC converter, the first switching leg and the second switching leg configured to merge the first resonant LC converter and the second resonant LC converter using beat frequency modulation (BFM).

The present invention additionally provides a method of operating a photovoltaic that includes electrically coupling the photovoltaic to the inventive microinverter disclosed herein.

### BRIEF DESCRIPTION OF THE DRAWINGS

The present invention is further detailed with respect to the following drawings that are intended to show certain aspects of the present of invention, but should not be construed as limit on the practice of the invention, wherein:

FIG. 1 shows a the beat frequency modulation (BFM) method according to embodiments of the present invention;

FIG. 2 shows a converter topology derivation according to embodiments of the present invention;

FIG. 3 shows a BFM microinverter configuration according to embodiments of the present invention;

FIG. 4A is a graph showing resonant LLC tank gain versus normalized switching frequency for different quality factors;

FIG. 4B is a block diagram showing an equivalent resonant circuit according to embodiments of the present invention;

FIG. 5 is a block diagram of the microinverter control strategy according to embodiments of the present invention;

FIG. 6 is a block diagram of a modulation unit in the control scheme according to embodiments of the present invention;

FIG. 7 show a PWM generation unit in the control scheme according to embodiments of the present invention;

FIG. 8A is a graph showing simulation results for voltage and current of the grid of the inventive BFM microinverter;

FIG. 8B is a graph showing simulation results for voltage and current across the resonant tank of the inventive BFM microinverter;

FIG. 8C is a graph showing simulation results for resonant tank current over grid periods of the inventive BFM microinverter;

FIG. 8D is a graph showing simulation results for voltage waveforms of the input stage and output stage switches of the inventive BFM microinverter;

FIG. 8E is a graph showing simulation results for inverter current over grid periods of the inventive BFM microinverter;

FIG. 8F is a graph showing simulation results for current waveforms of the input stage and output stage switches of the inventive BFM microinverter;

FIG. 9A shows experimental results of the inventive BFM microinverter with resonant current Iᵣ: 60 Hz envelope along with a zoom scale for 100 kHz component;

FIG. 9B shows experimental results of the inventive BFM microinverter with voltage and current across resonant tank (soft-switching conditions are provided due to inductive current);

FIG. 10 shows experimental results of the inventive BFM microinverter with Voltage and current waveforms of the grid;

FIG. 11 shows using BFM single-stage microinverter configuration with a half-bridge structure at the grid side;

FIG. 12 shows an exemplary inventive PWM generation unit if reactive power control is desired; and

FIG. 13 shows an exemplary inventive control block diagram implementation of the microinverter.

### DETAILED DESCRIPTION OF THE INVENTION

The present invention has utility as a single-stage single-phase microinverter with a fully soft-switching operation for a wide range of input voltage and output load as a result of a new beat frequency modulation (BFM) which can be utilized in different topologies. The BFM microinverter has additional utility in that it utilizes a low number of components with a simple control strategy, which results in a low-cost and low-volume microinverter for high-frequency and highly efficient applications. According to embodiments, the inventive BFM is combined with the LLC-based microinverter, in which soft-switching conditions for all semiconductors are provided for a wide range with no auxiliary circuit. A simple single-phase DQ current controller is employed to regulate the output current.

It is to be understood that in instances where a range of values are provided that the range is intended to encompass not only the end point values of the range but also intermediate values of the range as explicitly being included within the range and varying by the last significant figure of the range. By way of example, a recited range of from 1 to 4 is intended to include 1-2, 1-3, 2-4, 3-4, and 1-4.

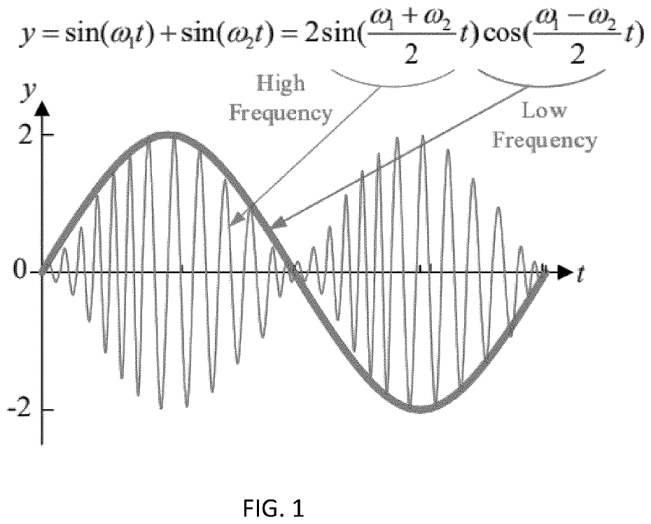

According to embodiments, beat frequency modulation (BFM) is illustrated in FIG. 1. Mathematically, the summation of two high-frequency sinusoidal waveforms with two different frequencies (such that the frequency difference between the two waveforms is considerably lower than the frequency of each waveform) would result in a high-frequency sinusoidal waveform with a low-frequency envelope as can be seen in Equation 1.

$$\text{?} = sin \text{?} + sin \text{?} = \text{?} cos \text{?} \qquad Equation 1$$

$$\text{?} \text{indicates text missing or illegible when filed}$$

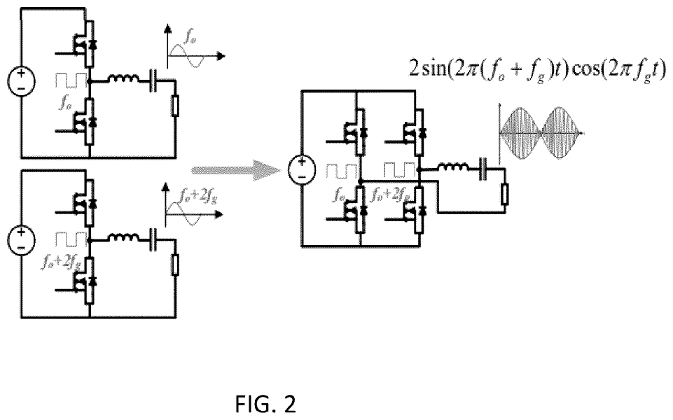

Assuming that the frequency deference is equal to twice the grid frequency (e.g., 120 Hz), the resulting envelope would be a 60 Hz sinusoidal waveform. Therefore, the inventive microinverter is obtained by combining two high-frequency sinusoidal waveforms using two series resonant converters as shown in FIG. 2. The frequencies of sinusoidal currents generated by the two series resonant LC converters are f₀ and f₀+2f_{g}, where f₀ is the switching frequency of the converter and f_{g} is the grid frequency. The switching frequency is a little higher than the resonance frequency of the LC networks to provide zero voltage switching (ZVS) conditions for the main converter switches. Then, two LC networks can be merged through two switching legs with the above-mentioned frequency operation, resulting in the desired high-frequency waveform with the grid-frequency envelope.

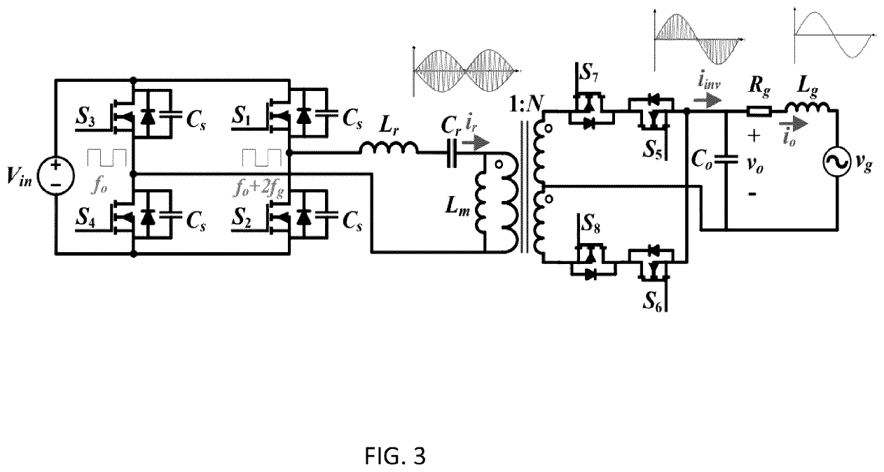

FIG. 3 shows an embodiment of the inventive BFM microinverter. As can be observed, the inventive microinverter is configured based on the LLC resonant network in which the magnetizing inductance Lₘ is added to the previous LC series resonant tank to provide a wider softswitching range for a wide input voltage range suitable for PV applications. The proposed BFM is applied to the LLC network using two switching legs. At the output stage, the conventional diode bridge rectifier and full bridge unfolder are merged to reduce the number of semiconductor components which results in a single-stage single-phase microinverter configuration. Eventually, utilizing a capacitor at the output, the envelope of the inverter current (iᵢₙᵥ) is provided to the connected grid or output load. As a result, a grid-frequency sinusoidal waveform is injected to the connected grid.

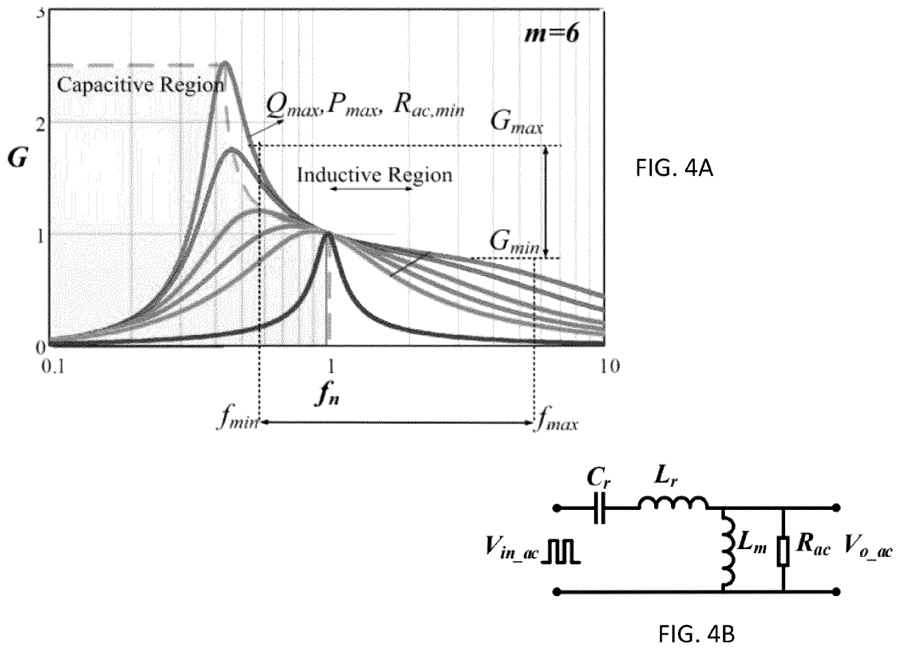

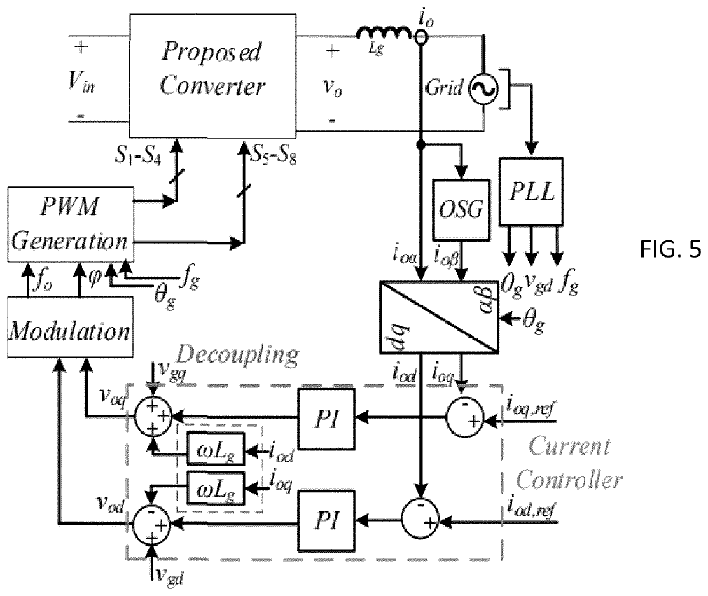

The resonant LLC tank of embodiments of the inventive microinverter is designed similar to DC-DC resonant converters with fundamental harmonic approximation (FHA). The resonant tank gain in Equation 2 is derived by analyzing its equivalent circuit shown in FIG. 4B. The gain diagram of the LLC resonant tank versus normalized switching frequency fₙ for different quality factors Q=ωᵣLᵣ/R_{ac} is shown in FIG. 4A. According to the required minimum and maximum DC gain of the converter (Vᵢₙ=20~40V, Vₒᵤₜ=340V), a suitable value for inductance ratio m=(Lᵣ+Lₘ)/Lᵣ is selected. Then based on the maximum output power (Pₒᵤₜd=250 W), a maximum quality factor is selected such that the inventive microinverter can operate in a reasonable frequency range to provide the required gain at the inductive ZVS region. Therefore, the inductive region operation is ensured for the whole range of input voltage and output power. Then, the resonant components are obtained solving Equations 2-7.

$$G = \text{?} = \frac{\text{?}}{\sqrt{\text{?}}} \qquad Equation 2$$

$$Q - \frac{\sqrt{\frac{\text{?}}{\text{?}}}}{\text{?}} \qquad Equation 3$$

$$\text{?} - \frac{8}{\text{?}} \frac{\text{?}}{\text{?}} \text{?} \qquad Equation 4$$

$$\text{?} = \frac{\text{?}}{\text{?}} \qquad Equation 5$$

$$\text{?} - \frac{\text{?}}{\text{?}} \qquad Equation 6$$

$$\text{?} - \frac{\text{?} + \text{?}}{\text{?}} \qquad Equation 7$$

$$\text{?} \text{indicates text missing or illegible when filed}$$

The utilized values in the design of the inventive microinverter are obtained as N=12, fᵣ=100 kHz, Gₘₐₓ=1.6, Gₘᵢₙ=0.8, Qₘₐₓ=0.4, m=7, Cᵣ=1.25 uF, Lᵣ=2 μH and Lₘ=12 μH.

Considering the aforementioned conditions for the LLC resonant tank, the fully soft-switching operation is provided for embodiments of the inventive microinverter switches. The S₁-S₂ leg is switched in complementary mode with a PWM signal in which the duty cycle is % 50, and the frequency is equal to f₀+2f_{g}. A suitable dead time is considered for the switches to provide soft-switching operation. A similar PWM signal with a frequency equal to f₀ is applied to the S₃-S₄ leg. Therefore, the S₁-S₄ switches are turned on at zero voltage zero current switching (ZVZCS) condition. In addition, ZVS turn-off conditions are provided for S₁-S₄ due to the snubber capacitors across these switches. The output stage switches S₅-S₈ are switched according to the positive and negative half cycles of the output voltage. In the positive half cycle of the output voltage (grid frequency cycle), S₅ and S₆ are on, and the body diodes of the S₇ and S₈ are conducting at ZCS conditions according to the current direction of the transformer. Therefore, S₇ and S₈ can be turned on in synchronous with their body diodes to reduce the conduction losses. The ZCS conditions are provided for both turn-on and turn-off instants of the S₅ and S₆. For the negative half cycle, S₇ and S₈ are on, and the body diodes of the S₅ and S₅ are conducting at ZCS conditions. Similar to the positive half cycle, switches can be turned on in synchronous with their body diodes, and ZCS conditions are provided for S₇ and S₈.

The grid-connected control scheme of the inventive microinverter is shown in FIG. 5. As can be seen, to regulate the output current of the inventive microinverter, a single-phase DQ current controller is utilized in which an orthogonal signal generation (OSG) technique is used to provide a virtual orthogonal component of the grid current in αβ frame [10]. In this method, the OSG unit generates the β component of the grid current which is a 90-degree delayed version of that signal. The utilized OSG unit makes the controller more stable due to independence of system parameters and operating frequency. Furthermore, the employed OSG does not produce any additional delay to the controller.

The output current of the microinverter (iₒ) is synchronized with the grid voltage through a phase-locked loop (PLL) unit. As a result, the grid frequency fₛ, and grid angle θ_{g} along with the D component of the grid voltage V_{gd} are obtained from the PLL unit. These values are used as references for the PWM unit to synchronize the output current of the microinverter with the grid volage. The DQ frame references of the current controller are calculated according to desired output power calculations. Then, a simple PI controller is employed in both D and Q axes of the currents to regulate the DQ components of the current. The PI controller is designed based on the simplified system model of the converter. Considering a non-ideal inductor filter (L_{g} in series with R_{g}) as the plant in the system model of the proposed microinverter, the k_{P} and kᵢ of the PI are selected such that the open-loop plant pole s=−R_{g}/L_{g} are canceled by the compensator zero s=−kᵢ/kₚ. As can be seen in the block diagram of the control system in FIG. 5, to eliminate the coupling effect of the DQ axes in the converter, decoupling terms are added in the control system.

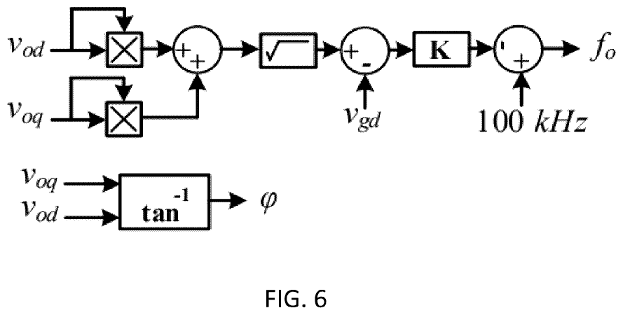

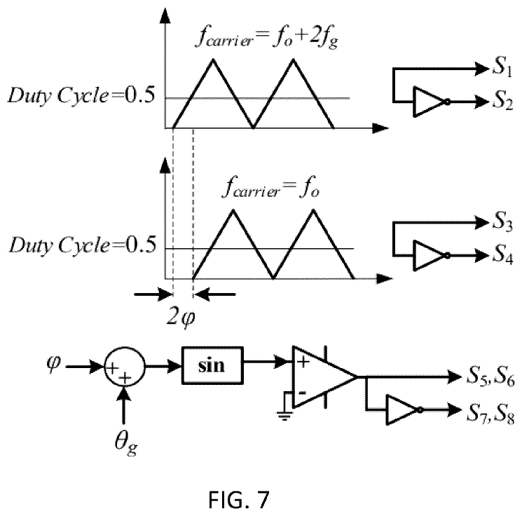

The inventive beat frequency modulation and PWM generation units are illustrated in FIGS. 6 and 7, respectively. As can be observed, the switching frequency (f₀) and phase angle (φ) of the microinverter are obtained from DQ components generated by the current controller according to the relationships between the phase and amplitude, and DQ terms in a single-phase system. The current amplitude at the output is changed by adjusting f₀ which is applied directly to the LLC resonant tank. By changing the switching frequency, the voltage gain of the resonant tank is changed, and thus, the desired amplitude of the current at the output is obtained. Also, the phase angle of the output current is changed by adjusting the phase shift between the two switching legs at the input stage of the inventive microinverter.

The beat frequency modulation (BFM) method of the present invention is applied to different power converters to obtain a BFM microinverter with a fully softs-witching operation. The inventive BFM microinverter is presented based on the LLC resonant converter, in which soft-switching conditions are provided for all switches. The unfolder and rectifier of the microinverter are merged to obtain a single-stage single-phase structure. The control strategy of the BFM microinverter is based on the single-phase DQ frame current control. Modulation and PWM generation units employed in the control scheme are illustrated. The design of LLC resonant components is discussed. Simulation results are displayed to show the soft-switching operation and BFM method operation.

### Simulation and Experimental Results

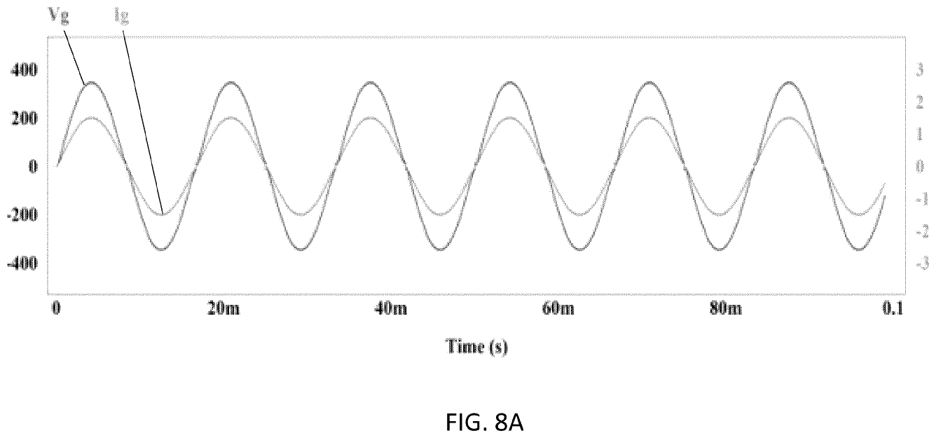

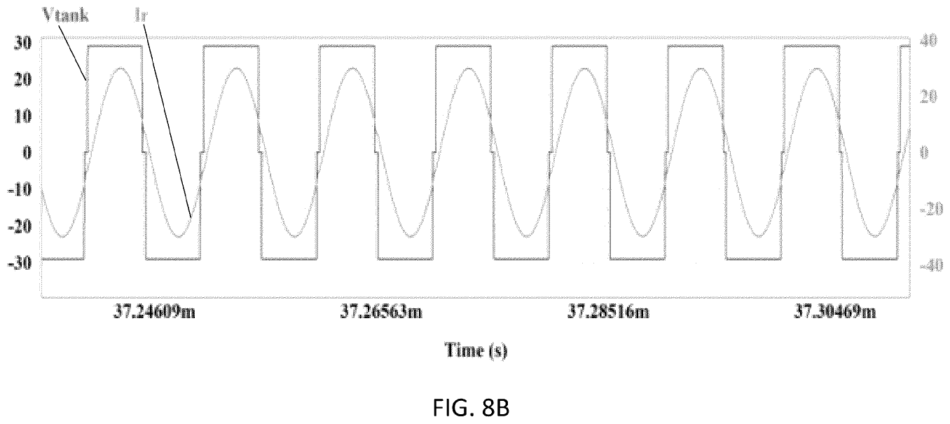

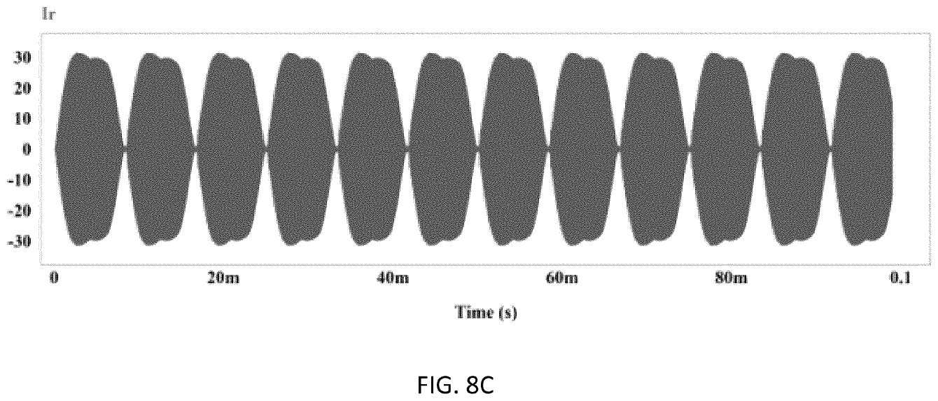

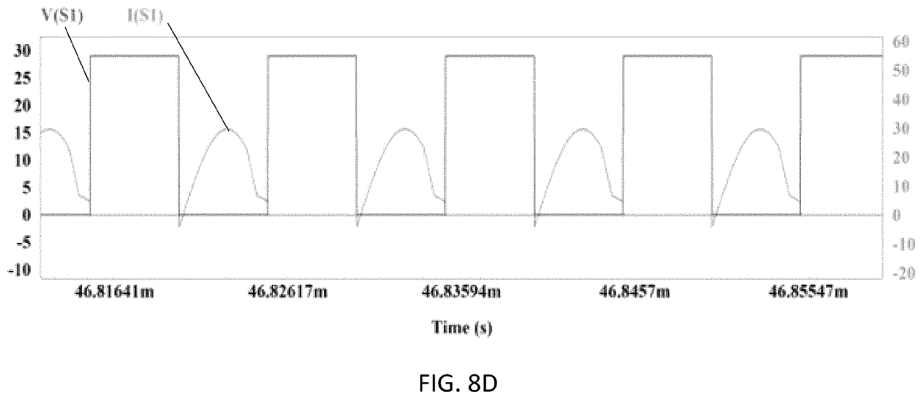

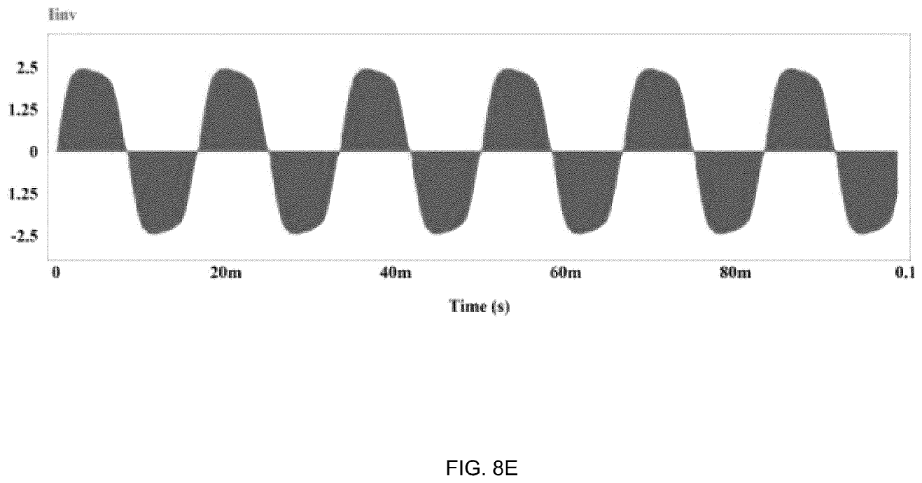

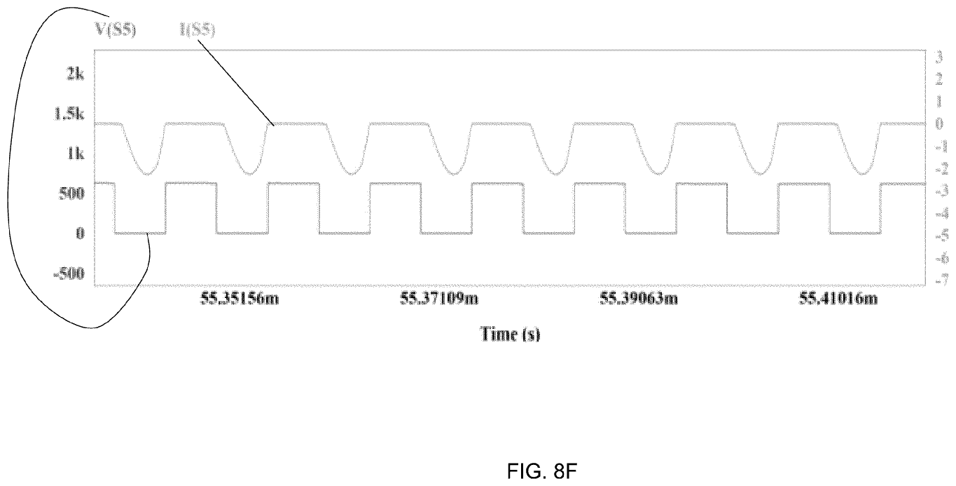

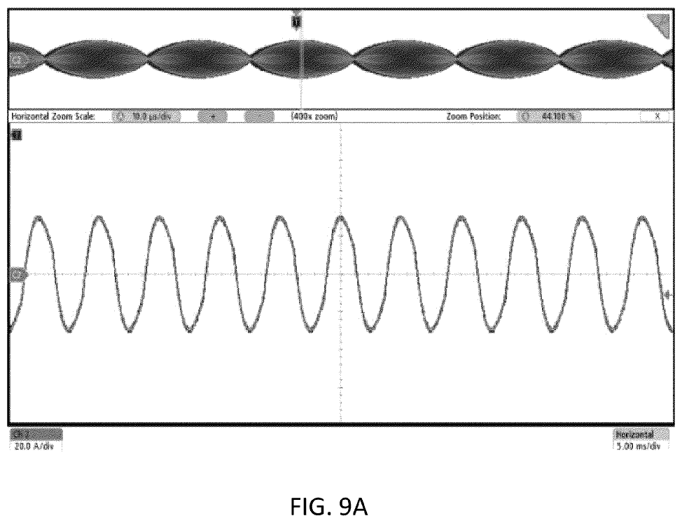

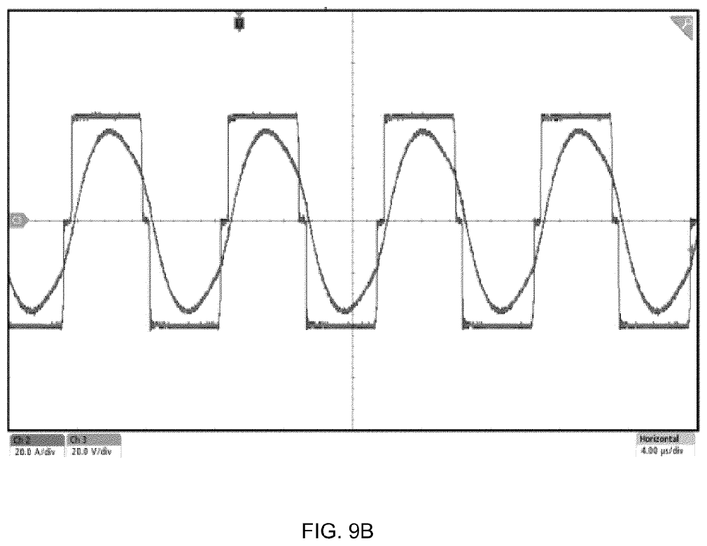

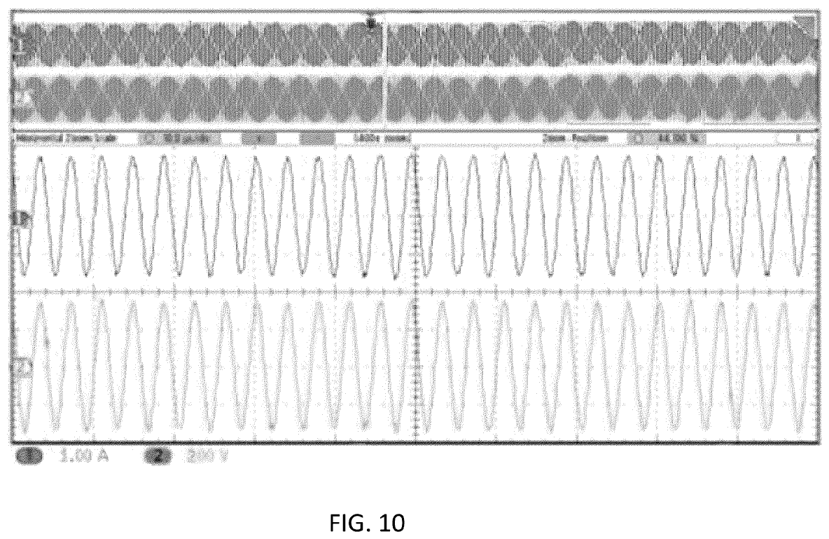

The simulation results of embodiments of the inventive BFM microinverter are displayed in FIGS. 8A-8F. The inventive microinverter is designed for an input voltage Vᵢₙ=20~40V, an output voltage Vₒᵤₜ=240 Vrms, a nominal switching frequency f_{sw}=100 kHz, and a maximum output power Pₒᵤₜ=250 W. The voltage and current of the grid are shown in FIG. 8A. The voltage and current across the resonant tank are shown in FIG. 8B. As can be seen, the current is inductive, and thus, the soft-switching condition is provided. In FIG. 8C, the resonant tank current is displayed over grid periods. The voltage and current waveforms of the input stage and output stage switches are shown in FIG. 8D and FIG. 8F, in which soft-switching conditions are provided for both turn-on and turn-off instants. To confirm the theoretical analysis, experimental results are shown in FIG. 9A and FIG. 10 in which the functionality and validity of the inventive BFM method are shown.

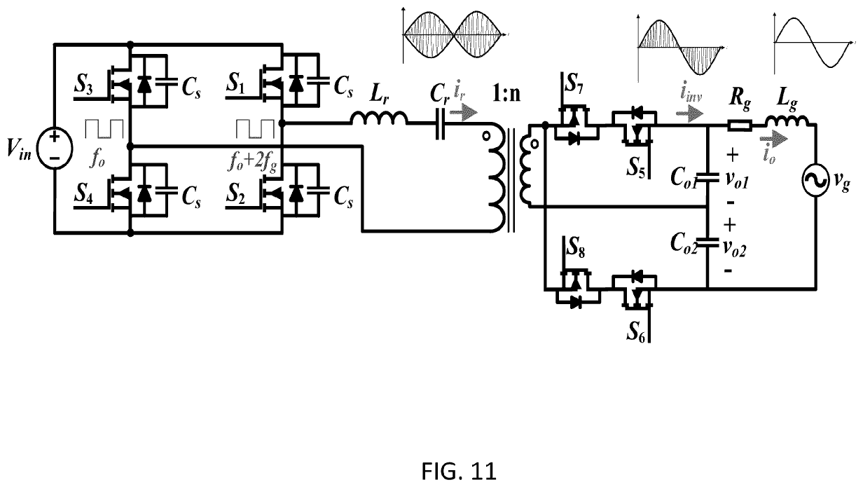

FIG. 11 shows an inventive BFM microinverter in which a four-quadrant half-bridge with two output capacitors are utilized to replace the three-winding transformer by a two-winding transformer. This structure has some advantages over three-winding structure as it eliminates the spikes caused by leakage current and employs the transformer magnetization properly.

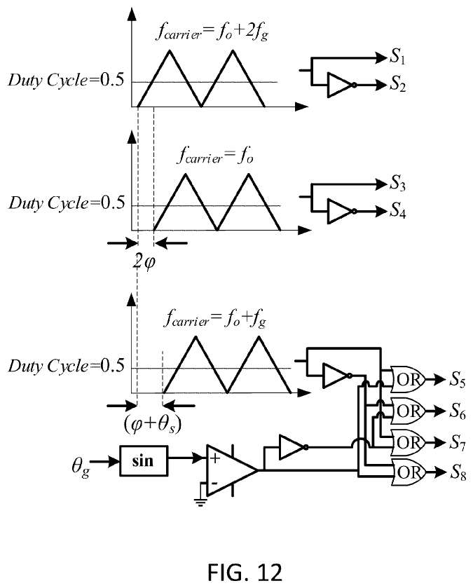

FIG. 12 shows a PWM generation unit of the inventive microinverter in which the secondary side switches (S₅-S₈) are required to be switched with a high frequency PWM with the carrier frequency of f₀+f_{g} and the phase of φ+θs to provide none-unity power factors of the output current. The phase shift between primary side and secondary side (θs) is obtained from series resonant converter design based on the LBT where the resonant tank current becomes zero in a resonant period. The value of θS is constant during a line cycle and it can be updated based on the output power and quality factor of the resonant tank. The switching frequency f₀ and the carrier phase o are obtained from the modulation unit in which the Ud and Uq of the current controller are converted to the amplitude and phase of the output current using the DQ equations. The amplitude and phase of the output current are determined by the switching frequency and the phase obtained from modulation unit, respectively.

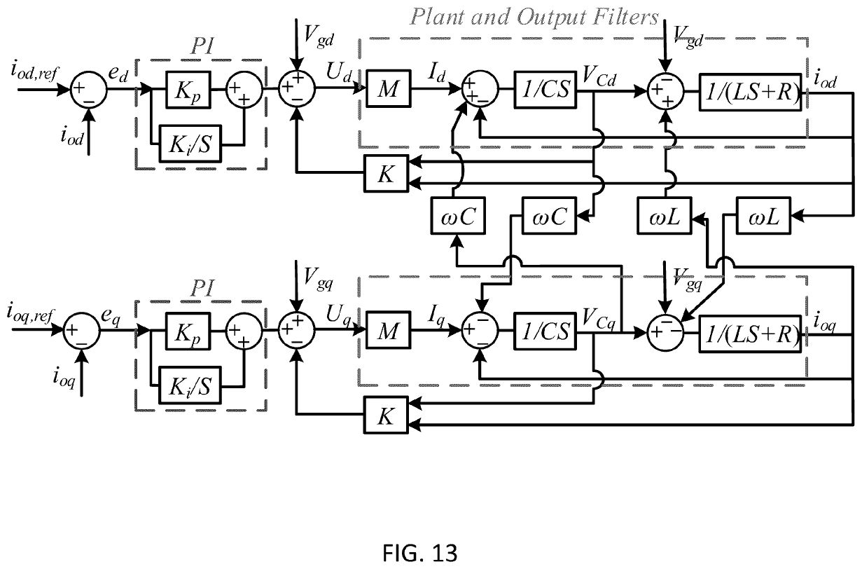

FIG. 13 shows an microinverter control system is shown in FIG. 13 in which the PI controllers and state feedbacks (U=−KX) are designed by the linear quadratic tracking (LQT). FIG. 13 provides more details about the design of the current controller shown in FIG. 5.

### REFERENCES

[1] S. Kouro, J. I. Leon, D. Vinnikov and L. G. Franquelo, “Grid-Connected Photovoltaic Systems: An Overview of Recent Research and Emerging PV Converter Technology,” in IEEE Industrial Electronics Magazine, vol. 9, no. 1, pp. 47-61, March 2015.
[2] K. Alluhaybi, I. Batarseh and H. Hu, “Comprehensive Review and Comparison of Single-Phase Grid-Tied Photovoltaic Microinverters,” in IEEE Journal of Emerging and Selected Topics in Power Electronics, vol. 8, no. 2, pp. 1310-1329 June 2020.
[3] Y. Chen and D. Xu, “Review of Soft-Switching Topologies for SinglePhase Photovoltaic Inverters,” in IEEE Transactions on Power Electronics, vol. 37, no. 2, pp. 1926-1944 February 2022.
[4] Y. Chen et al., “A ZVS Grid-Connected Full-Bridge Inverter with a Novel ZVS SPWM Scheme,” in IEEE Transactions on Power Electronics, vol. 31, no. 5, pp. 3626-3638 May 2016.
[5] R. Hasan, W. Hassan and W. Xiao, “PV Microinverter Solution for High Voltage Gain and Soft Switching,” in IEEE Journal of Emerging and Selected Topics in Industrial Electronics, vol. 3, no. 2, pp. 352-361, April 2022.
[6] S.-W. Jo, H. Seok, J.-S. Kim and M. Kim, “Resonant Flyback PV Microinverter With Low Component Count,” 2020 IEEE Applied Power Electronics Conference and Exposition (APEC), New Orleans, LA, USA, 2020, pp. 629-635.
[7] H. Wu, X. Tang, J. Zhao and Y. Xing, “An Isolated Bidirectional Microinverter Based on Voltage-in-Phase PWM-Controlled Resonant Converter,” in IEEE Transactions on Power Electronics, vol. 36, no. 1, pp. 562-570, January 2021.
[8] M. D'Antonio, S. Chakraborty and A. Khaligh, “Design Optimization for Weighted Conduction Loss Minimization in a Dual-Active-BridgeBased PV Microinverter,” 2020 IEEE Energy Conversion Congress and Exposition (ECCE), Detroit, MI, USA, 2020, pp. 6008-6015.
[9] A. K. Bhattacharjee and I. Batarseh, “Sinusoidally Modulated AC-Link Microinverter Based on Dual-Active-Bridge Topology,” in IEEE Transactions on Industry Applications, vol. 56, no. 1, pp. 422-435, January February 2020.
[10] M. Ebrahimi, S. A. Khajehoddin and M. Karimi-Ghartemani, “Fast and Robust Single-Phase DQ Current Controller for Smart Inverter Applications,” in IEEE Transactions on Power Electronics, vol. 31, no. 5, pp. 3968-3976 May 2016.

While at least one exemplary embodiment has been presented in the foregoing description and attached appendix, it should be appreciated that a vast number of variations exist. It should also be appreciated that the exemplary embodiment or exemplary embodiments are only examples, and are not intended to limit the scope, applicability, or configuration of the described embodiments in any way. Rather, the foregoing description and incorporated references will provide those skilled in the art with a convenient roadmap for implementing the exemplary embodiment or exemplary embodiments. It should be understood that various changes may be made in the function and arrangement of elements without departing from the scope as set forth in the appended claims and the legal equivalents thereof.

1. A Beat Frequency Modulation (BFM) system for generating a low frequency reference waveform, the system comprising:
two or more converters connected in series or parallel or cascaded, each converter comprising at least a power switch configured to generate a high frequency power signal controlled by BFM modules at their respective outputs;
a frequency control module configured to operate a BFM carrier signal of each of the converters at different frequencies, thereby creating an envelope of a resulting signal containing a desired low frequency reference signal; and
a rectifier connected to outputs of the converters, the rectifier configured to rectify the high frequency signal with the low frequency envelope shape, thereby generating a low frequency sinusoidal waveform.

2. A microinverter for use with a photovoltaic (PV) system, the microinverter comprising:
a LC resonant tank comprising:
a first resonant LC converter configured to generate a first current having a frequency of a sinusoidal current of F₀;
a second resonant LC converter configured to generate a second current having a frequency of a sinusoidal current of F₀+2F_{g}, where f₀ is the switching frequency of the first resonant LC converter and f_{g} is a grid frequency; and
a first switching leg associated with the first resonant LC converter and a second switching leg associated with the second resonant LC converter, the first switching leg and the second switching leg configured to merge the first resonant LC converter and the second resonant LC converter using beat frequency modulation (BFM); and
a magnetizing inductance Lₘ electrically connected to the LC resonant tank;
wherein the LC resonant tank and the magnetizing inductance Lₘ form an LLC resonant network.

3. The microinverter of claim 2 further comprising an output stage electrically connected to the LLC resonant network.

4. The microinverter of claim 3 wherein the output stage comprises a diode bridge rectifier, a full bridge unfolder, and a capacitor.

5. The microinverter of claim 4 wherein the diode bridge rectifier and the full bridge unfolder are merged into a single component.

6. The microinverter of claim 2 wherein the first resonant LC converter and the second resonant LC converter are arranged in series.

7. The microinverter of claim 2 wherein the switching frequency F₀ is greater than a resonance frequency of the first LC converter and the second LC converter.

8. The microinverter of claim 2 wherein BFM comprises summing a first waveform of the sinusoidal current of the first current and a second waveform of the sinusoidal current of the second current to obtain a high-frequency sinusoidal waveform with a low-frequency using the following equation:
$$y = sin ( {ω}_{1} t ) + sin ( {ω}_{2} t ) = 2 sin ( \frac{{ω}_{1} + {ω}_{2}}{2} t ) cos ( \frac{{ω}_{1} - {ω}_{2}}{2} t ) .$$

9. The microinverter of claim 8 wherein a frequency difference between the first waveform and the second waveform is lower than the frequency of each of the first waveform and the second waveform independently.

10. The microinverter of claim 2 wherein the magnetizing inductance Lₘ is configured to provide a wider soft-switching range for a wide input voltage range suitable for PV applications.

11. The microinverter of claim 2 wherein the microinverter is a single-stage microinverter.

12. The microinverter of claim 2 wherein the microinverter is a single-phase microinverter.

13. The microinverter of claim 2 wherein the microinverter has a soft-switching operation for a wide range of input voltage and output load.

14. A method of operating a photovoltaic comprising:
electrically coupling the photovoltaic to a microinverter of claim 2.

15. The BFM system of claim 1 further comprising a component for summing a first waveform of the low frequency sinusoidal waveform of a first current and a second waveform of the the low frequency sinusoidal waveform of the second current to obtain a high-frequency sinusoidal waveform with a low-frequency using the following equation:
$$y = sin ( {ω}_{1} t ) + sin ( {ω}_{2} t ) = 2 sin ( \frac{{ω}_{1} + {ω}_{2}}{2} t ) cos ( \frac{{ω}_{1} - {ω}_{2}}{2} t ) .$$

16. The microinverter of claim 15 wherein a frequency difference between the first waveform and the second waveform is lower than the frequency of each of the first waveform and the second waveform independently.
